(19) United States
(12) Patent Application Publication
(10) Pub. No.: US 2025/0035819 A1
(43) Pub. Date: Jan. 30, 2025

(54) COMPOSITE OPTICAL FILM AND DISPLAY DEVICE COMPRISING SAME

(71) Applicant: LG ELECTRONICS INC., Seoul (KR)

(72) Inventors: Naree KIM, Seoul (KR); Dongjin YOON, Seoul (KR); Seunghwan CHA, Seoul (KR); Sangtae PARK, Seoul (KR)

(73) Assignee: LG ELECTRONICS INC., Seoul (KR)

(21) Appl. No.: 18/708,412

(22) PCT Filed: Jan. 10, 2022
(86) PCT No.: PCT/KR2022/000364

§ 371 Date: May 8, 2024

(51) Int. Cl. G02B 1/11; G02B 1/14; H01L 25/075; H01L 33/58

(52) U.S. Cl. CPC G02B 1/11; G02B 1/14; H01L 25/0753; H01L 33/58

(57) ABSTRACT

The present disclosure is applicable to the technical field of display devices and relates to, for example, a display device which uses a composite optical film and a light-emitting diode (LED). To achieve the aforementioned objective, the present disclosure comprises: a display panel; and a composite optical film which is positioned on the display panel, wherein the composite optical film includes an adhesive layer which is attached to the display panel and includes a light scattering agent. The refractive index of the light scattering agent may be greater than that of the adhesive layer.

### TECHNICAL FIELD

The present disclosure is applicable to technical fields related to display devices, and relates to, for example, a display device that uses a composite optical film and light emitting diodes (LEDs).

### BACKGROUND ART

Recently, display devices with excellent characteristics such as thinness and flexibility have been developed in the field of display technology.

Light emitting diodes (LEDs) have been gradually miniaturized and used as pixels of a display device.

The display device may be provided with film(s) capable of providing optical functions. Here, this film providing such optical functions may mainly perform the role of providing black color to the display device, and may also provide the display device with functions such as anti-reflection or the like.

Meanwhile, these films may also perform a protective function for the display device. In order to implement various types of display devices or flexible display devices, flexibility of such protective films is required.

However, the optical properties of such films have disadvantages in terms of block color implementation, anti-reflection, etc. of the display device.

In addition, when a general film is placed on a display panel, depending on an inclination of an LED chip, light emitted from the LED may have a directivity angle that is biased toward one side of the chip inclination.

Accordingly, light emitted from the LED is characterized in that the directivity angle of light is not uniform with respect to the center of the LED chip and at the same time is biased toward one side of the chip.

At this time, when a general film is used, the non-uniform light distribution due to the chip inclination may be directly exposed outside. This may cause a luminance deviation phenomenon in which light emitted from the display panel is biased in a specific direction. As a result, there may occur color differences depending on viewing angles of the display device.

Therefore, methods for addressing these problems should be researched and developed.

### DISCLOSURE

### Technical Problem

An object of the present disclosure is to provide a composite optical film that can provide superior optical functions to a display device, and the display device including the same.

Another object of the present disclosure is to provide a composite optical film capable of compensating for differences in light distribution of a display device, and the display device including the same.

Another object of the present disclosure is to provide a composite optical film capable of compensating for differences in directivity angles of LEDs used as pixels of a display device, and a display device including the same.

### Technical Solutions

In accordance with an aspect of the present disclosure, a display device may include: a display panel; and a composite optical film disposed on the display panel, wherein the composite optical film includes: an adhesive layer attached to the display panel and configured to contain a light scattering agent. The light scattering agent may have a higher refractive index than the adhesive layer.

The light scattering agent may include at least one of Zr, Si, Ti, Zn, BaS, and oxides thereof.

The light scattering agent may include Zr oxide.

The refractive index of the light scattering agent may be about 1.3 to 2.8.

The content of the light scattering agent may be about 0.01% to 20% compared to the adhesive layer.

The composite optical film may include: a transparent protective layer disposed on the adhesive layer; a black dye layer disposed on the transparent protective layer; and an optical function layer disposed on the black dye layer to provide at least one optical function.

The optical functional layer may include at least one of an anti-reflection film (AR) or Anti-Glare (AG) film, a low-reflection (LR) film, and an anti-fingerprint (AF) film.

The display panel may include red, green, and blue light emitting diodes (LEDs) configured to constitute each pixel.

The light scattering agent may compensate for a difference in directivity angle between the light emitting diodes (LEDs).

The light scattering agent may compensate for light distribution that is biased to one side due to a tilt of a crystal plane of each of the LEDs or a tilt caused by soldering or adhesion of the LED.

The display device may further include a black layer disposed at a side surface of the LED.

The light scattering agent may have a size of about 0.01 to 10 μm.

In accordance with another aspect of the present disclosure, a composite optical film disposed on a display panel may include: an adhesive layer attached to the display panel and configured to contain a light scattering agent; a transparent protective layer disposed on the adhesive layer; a black dye layer disposed on the transparent protective layer; and an optical function layer disposed on the black dye layer to provide at least one optical function.

### Advantageous Effects

The display device according to the embodiments of the present disclosure can obtain the following effects.

First, the luminance deviation phenomenon in which light emitted from a display panel is biased in a specific direction may be resolved. Therefore, it is possible for the display device to implement uniform color senses without causing color differences depending on the viewing angle of the display device.

In other words, the phenomenon (i.e., non-uniform reduction in luminance) in which image colors appear differently to a user who views the display panel depending on the user's position and angle with respect to the display panel can be improved.

Additionally, according to an exemplary embodiment of the present disclosure, non-uniform light distribution due to the chip inclination of the LEDs can be made uniform.

### DESCRIPTION OF DRAWINGS

FIG. 1 is a cross-sectional schematic diagram illustrating a display device provided with a composite optical film according to an embodiment of the present disclosure.

FIG. 2 is a cross-sectional schematic diagram illustrating a composite optical film according to an embodiment of the present disclosure.

FIG. 3 is a cross-sectional view illustrating a specific example of a display device provided with a composite optical film according to an embodiment of the present disclosure.

FIG. 4 is a cross-sectional view illustrating another specific example of a display device provided with a composite optical film according to an embodiment of the present disclosure.

FIG. 5 is a cross-sectional schematic diagram illustrating the scattering effect of the display device provided with a composite optical film according to an embodiment of the present disclosure.

FIG. 6 is a conceptual view illustrating an example of light scattering agents for the composite optical film according to an embodiment of the present disclosure.

FIGS. 7 and 8 are cross-sectional schematic diagrams illustrating example states that compensate for light distribution of the display device provided with a composite optical film according to an embodiment of the present disclosure.

FIG. 9 is a graph showing changes in white luminance for each viewing angle of the composite optical film according to an embodiment of the present disclosure.

FIG. 10 is a graph showing changes in luminance for each pixel affected by the composite optical film according to comparative examples of the present disclosure.

FIG. 11 is a graph showing changes in luminance for each pixel affected by the composite optical film according to an embodiment of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other clement or there may be an intermediate element between them.

The display device described herein is a concept including all display devices that display information with a unit pixel (sub-pixel) or a set of unit pixels (sub-pixels). Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting diode mentioned in this specification is a concept including an LED, a micro-LED, and the like, and may be used interchangeably therewith.

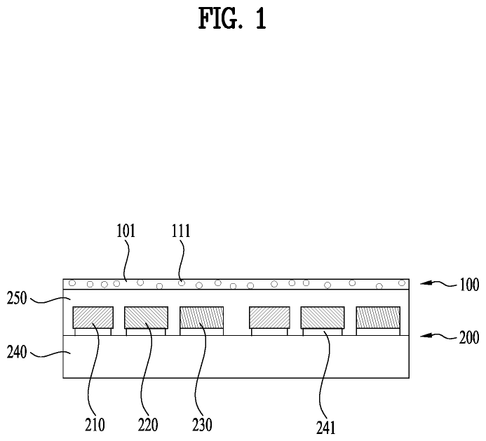

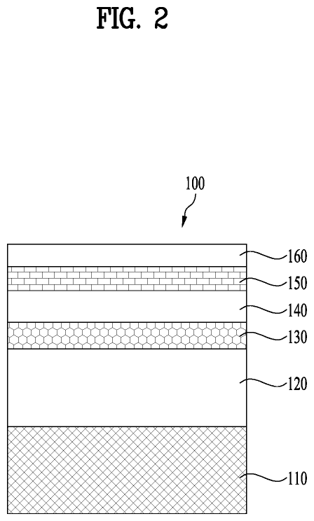

FIG. 1 is a cross-sectional schematic diagram illustrating a display device provided with a composite optical film according to an embodiment of the present disclosure. FIG. 2 is a cross-sectional schematic diagram illustrating a composite optical film according to an embodiment of the present disclosure.

Referring to FIG. 1, a display panel 200 may implement image(s) using sub-pixels (210, 220, 230) arranged on a substrate 240. An encapsulation layer 250 may be formed on the sub-pixels (210, 220, 230).

A composite optical film 100 may be located on the display panel 200. In this way, the composite optical film 100 may be attached to the display panel 200. The display panel 200 to which the composite optical film 100 is attached will hereinafter be referred to as a display device for convenience of description.

Here, the composite optical film 100 may include a matrix 101 that is attached to the display panel 200 and includes one or more light scattering agents 111. Referring to FIG. 2, this matrix 101 may include an adhesive layer 110 and a transparent protective layer 120. For example, the light scattering agent 111 may be located within the adhesive layer 110.

The light scattering agent 111 may cause light scattering, which is a kind of random reflection, by interfering with straightness of light emitted from a light source constituting the sub-pixels (210, 220, 230). Therefore, the light scattering agent 111 may prevent occurrence of the luminance deviation phenomenon in which light emitted from the sub-pixels (210, 220, 230) is biased in a specific direction.

In addition, the light scattering agent 111 may improve the phenomenon (for example, non-uniform reduction in luminance) in which colors appear differently according to the left and/or right positions and angles with respect to the position of the substrate 240.

As an exemplary embodiment, the display panel 200 may be a flexible display.

A flexible display may include, for example, a display that can be curved, bent, twisted, folded, or rolled by external force.

Furthermore, a flexible display may be, for example, a display fabricated on a thin flexible substrate that can be curved, bent, folded, or rolled like paper while maintaining display characteristics of a conventional flat panel display.

In a state in which the flexible display is not bent (for example, a state in which the flexible display has an infinite radius of curvature, hereinafter referred to as a first state), a display region of the flexible display becomes flat in surface. In a state (for example, a state in which the flexible display has an infinite radius of curvature, hereinafter referred to as a second state) in which the flexible display is curved or bent by external force in the first state, the display region may become a curved surface. Information displayed in this second state may be visual information displayed on the curved surface. Such visual information can be implemented by independently controlling light emission of sub-pixels arranged in a matrix form. Here, each of the sub-pixels may refer to, for example, a minimum unit for implementing one color.

For example, the sub-pixel of the display panel 200 may be implemented by a light emitting device. According to one embodiment of the present disclosure, a light emitting diode (LED) will hereinafter be exemplified as a type of semiconductor light emitting device that converts current into light. The light emitting diode (LED) may be formed in a small size. In the case of a flexible display, the LED may serve as a sub-pixel even in the second state.

The substrate 240 may include glass or polyimide (PI). In order to implement the flexible display, the substrate 240 may be made of any insulating and flexible material, for example, any one of PEN, PET, etc. Additionally, the substrate 240 may be made of either a transparent or opaque material.

The substrate 240 may be a wiring substrate on which the wiring electrode 241 is disposed, and thus a wiring electrode 241 may be located on the substrate 240.

The encapsulation layer 250 may be disposed on the substrate 240 where a wiring electrode 241 is located. The encapsulation layer 250 may be made of an insulating and flexible material such as polyimide (PI), PET, or PEN, and may be integrated with the substrate 240 to form one substrate.

Light emitting diodes (LEDs) forming each of the sub-pixels (210, 220, 230) may be connected to the wiring electrode 241. Hereinafter, as an example, the sub-pixel may have the same meaning as a light emitting diode (LED). Therefore, detailed description of the present disclosure will be given using the same reference numerals. For example, three sub-pixels may form a single pixel. That is, the red (R) LED 210, the green (G) LED 220, and the blue (B) LED 230 may form one pixel. As described above, such LEDs 1 may be semiconductor LEDs.

The semiconductor LEDs (210, 220, 230) forming such sub-pixels may be micro-LEDs each having a size of several to hundreds of microns. In some cases, the semiconductor LEDs (210, 220, 230) may be mini-LEDs, each of which has a size corresponding to dozens of times the size of each micro-LED. Here, the mini-LED may be different from the micro-LED in terms of the size and a stacked structure. Specifically, the mini-LED may further include a growth substrate for growing a semiconductor layer.

As an example of the semiconductor LEDs (210, 220, 230) forming the sub-pixel, a micro-LED or mini-LED may not only have an LED type in which each of the red (R), green (G), and blue (B) LEDs emits light independently, may but also have a stacked LED type in which one LED includes three color layers (i.e., red (R), green (G), and blue (B) layers).

A thin film transistor (TFT) may be connected to the wiring electrode 241 to implement an active matrix (AM)—type display device. For example, the substrate 240 may be a TFT substrate. As another example, the substrate 240 may be a passive matrix (PM)—type substrate.

In FIG. 1, the structure of the display panel 200 is simplified and briefly shown. Hereinafter, a detailed description of a specific configuration of the display panel 200 will be omitted for brevity.

As described above, the composite optical film 100 may be disposed on the display panel 200. The composite optical film 100 may include a light scattering agent 111. The light scattering agent 111 may be included in an adhesive layer 110. At this time, the light scattering agent 111 may have a higher refractive index than the adhesive layer 110.

Referring to FIG. 2, the composite optical film 100 may include a transparent protective layer 120, a black dye layer 130, and optical functional layers (140, 150, 160) that are sequentially stacked on the adhesive layer 110 including the light scattering agent 111.

As an exemplary embodiment, the optical functional layers (140, 150, 160) may include at least one of anti-reflection films (e.g., an AR or AG (anti-glare) film, a low-reflection (LR) film, and an anti-fingerprint (AF) film).

The transparent protective layer 120 may have flexibility and can protect the LEDs (210, 220, 230) from external impact. A flexible transparent protective layer 120 may be used to meet the demands of various types of display devices.

This transparent protective layer 120 may be adhered to the encapsulation layer 250 using the adhesive layer 110.

The black dye layer 130 may be formed of a black dye having a preset transmittance, and may reduce the degree to which the transparent protective layer 120 is exposed to ultraviolet (UV) light. For example, the black dye layer 130 may have a transmittance of 10% to 60%. At this time, the black dye layer 130 may include sunscreen (or sunscreen agent) to increase the sunscreen (or UV blocking) effect.

The black dye layer 130 may serve to increase a contrast ratio.

Meanwhile, the light scattering agent 111 may be a material with a relatively high refractive index and may have the effect of improving the refractive index. The light scattering agent 111 having such a high refractive index can result in the large scattering effect even when a small amount of light scattering agents is added.

As an exemplary embodiment, the light scattering agent 111 may include at least one of Zr, Si, Ti, Zn, BaS, and oxides thereof. For example, the light scattering agent 111 may include at least one of oxides of Zr, Si, Ti, Zn, and BaS. That is, the light scattering agent 111 may include at least one of oxides represented by ZrxOy, TixOy, SixOy, ZnxOy, and BaxSyOz.

Additionally, as an exemplary embodiment, the refractive index of the light scattering agent 111 may be 1.3 to 2.8.

As an exemplary embodiment, the content of the light scattering agent 111 may be 0.01% to 20% compared to the adhesive layer 110.

A diameter (size) of the light scattering agent 111 may be 0.01 to 10 μm.

For example, the light scattering agent 111 may have an amorphous particle shape with a median size of approximately 1 μm. This light scattering agent 111 may be added to the adhesive layer 110 through a dispensing process. The light scattering agent 111 having a small size as described above may have stability against the dispensing process. In addition, the light scattering agent 111 may have advantages in that it undergoes less sedimentation even after a curing process has been performed after completion of the dispensing process.

As an exemplary embodiment, the light scattering agent 111 may include Zr oxide (e.g., ZrO₂). Since this Zr oxide is a material with a high refractive index (e.g., 2.3), the Zr oxide may have a relatively large scattering effect.

For example, in the case where silicon oxide (SiO₂) is used as the adhesive layer 110 or at least one of the transparent protective layer 120, the black dye layer 130, and the optical functional layers (140, 150, 160) includes silicon oxide (SiO₂), the Zr oxide has a larger refractive index than silicon oxide (SiO₂), thereby causing the large scattering effect.

In this case, the content of Zr oxide may occupy 0.01 to 20% of the adhesive layer 110. This content of Zr oxide may be within an appropriate range when considering both transmittance of the adhesive layer 110 and the light scattering effect of the light scattering agent 111.

As such, the light scattering agent 111 may have a higher refractive index than at least one of the adhesive layer 110, the transparent protective layer 120, the black dye layer 130, and the optical functional layers (140, 150, 160).

In this way, if the light scattering agent 111 is made of a material that has a larger difference in refractive index compared to the refractive index of resin that forms the adhesive layer 110, the light scattering effect may be increased.

The refractive index of silicone resin is approximately 1.4 to 1.6. When silicone resin is used as the adhesive layer 110, the refractive index of the light scattering agent 111 is preferably greater than the refractive index of the silicone resin.

Meanwhile, considering adhesive strength, the thickness of the adhesive layer 110 may be 20 μm or more. A maximum thickness of the commonly used adhesive layer 110 may be 200 μm. Considering this situation, the thickness of the adhesive layer 110 may be 20 to 200 μm.

For example, the adhesive layer 110 may be directly attached to the display panel 200. In some cases, the adhesive layer 110 may be formed after being directly applied to the display panel 200.

When the composite optical film 100 is disposed on the display panel 200, the display panel 20 may have additional advantages in addition to the improvement in optical properties and protection functions.

In other words, if a defect occurs in LED element(s) of a lower part of the display panel and the defective LED is repaired (e.g., replacement or repair of such LED), some problems may occur in flatness of a polymer encapsulation layer located at an upper part of the display panel, which may cause visual and optical non-uniformity. However, the composite optical film 100 located on the display panel 200 can obviate these problems. Therefore, there is an advantage that repair of the defective LED can be performed smoothly and easily.

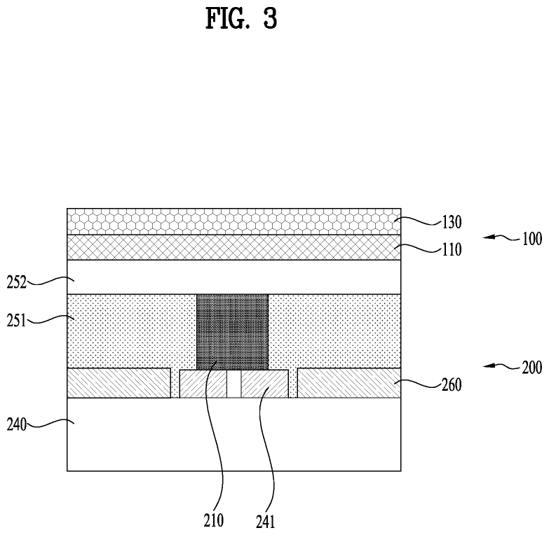

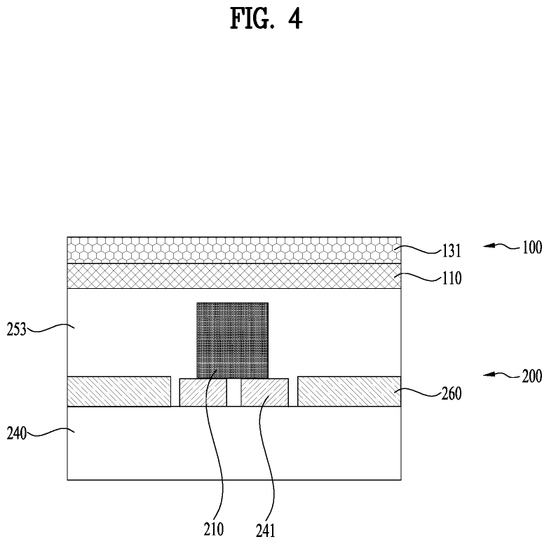

FIG. 3 is a cross-sectional view illustrating a specific example of the display device provided with the composite optical film according to an embodiment of the present disclosure. FIG. 4 is a cross-sectional view illustrating another specific example of the display device provided with the composite optical film according to an embodiment of the present disclosure.

Referring to FIG. 3, an example of the composite optical film 100 disposed on the display panel 200 is shown.

An image can be implemented by sub-pixels 210 (e.g., LEDs) arranged on the substrate 240. The LED 210 may be connected to the wiring electrode 241 disposed on the substrate 240. An encapsulation layer 252 may be formed on the LED 210 constituting the sub-pixel.

The composite optical film 100 may be located on the display panel 200. In this way, the composite optical film 100 can be attached to the display panel 200. The display panel 200 to which the composite optical film 100 is attached may hereinafter be referred to as a display device. FIG. 3 shows the composite optical film 100 in which the adhesive layer 110 and the black dye layer 130 are located.

As described above, the light scattering agent 111 may be included in the adhesive layer 110.

Meanwhile, as described above, the light scattering agent 111 may be included in the adhesive layer 110, so that the scattering effect described above can be implemented. That is, the composite optical film 100 including the adhesive layer 110 containing the light scattering agent 111 may prevent the luminance deviation phenomenon in which light emitted from the sub-pixels (210, 220, 230) is biased in a specific direction.

In addition, the composite optical film 100 including the adhesive layer 110 containing the light scattering agent 111 may improve the phenomenon (for example, non-uniform reduction in luminance) in which colors appear differently according to the left and/or right positions and angles with respect to the position of the substrate 240.

However, in some cases, the black chromaticity (blackness) of the composite optical film 100 may be lowered due to the light scattering agent 111 contained in the adhesive layer 110. In this case, a black layer 251 may be disposed on a side surface of the LED constituting the sub-pixel 210.

This black layer 251 may fill a peripheral portion (i.e., periphery) of the sub-pixel 210, resulting in improvement in black chromaticity.

A matrix (base or parent) material of the black layer 251 may be a polymer such as silicone, epoxy, acrylic, etc. The black layer 251 may include black dye and/or black pigment that is mixed with this polymer matrix material to produce a black color.

FIG. 4 shows an example of a display device in which a composite optical film 100 including a black dye layer 131 with adjusted transmittance is used instead of the black layer 251 located at the side surface of the LED.

That is, referring to FIG. 4, transmittance of the black dye layer 131 is adjusted instead of the black layer 251 located at a side surface of the LED constituting the sub-pixel 210, thereby compensating for a change in blackness (black color sense) caused by the light scattering agent 111.

For example, black chromaticity can be improved by lowering transmittance of the black dye layer 131 to about 10 to 30%. For example, when the black layer 251 located on the side of the LED forming the sub-pixel 210 is provided as shown in FIG. 3, transmittance of the black dye layer 130 may be 40 to 70%. In FIG. 4, transmittance of the black dye layer 131 may be 10 to 30%.

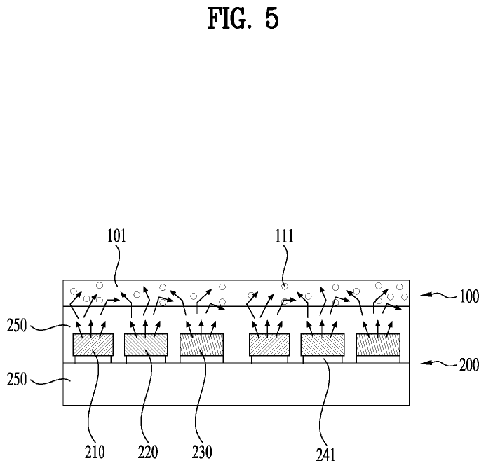

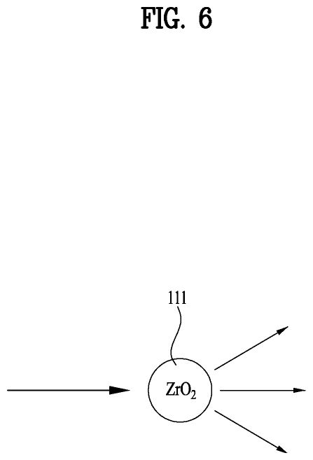

FIG. 5 is a cross-sectional schematic diagram illustrating the scattering effect of the display device provided with the composite optical film according to an embodiment of the present disclosure. FIG. 6 is a conceptual view illustrating an example of the light scattering agent for the composite optical film according to an embodiment of the present disclosure.

As described above, referring to FIG. 5, the composite optical film 100 according to an embodiment of the present disclosure may include a matrix 101 that is attached to the display panel 200 and includes a light scattering agent 111. For example, the light scattering agent 111 may be located within the adhesive layer 110.

The light scattering agent 111 may interfere with straightness of light emitted from the light source forming the sub-pixels (210, 220, 230) to cause light scattering that is one type of random reflection, thereby preventing the luminance deviation phenomenon in which light emitted from the sub-pixels (210, 220, 230) is biased in a specific direction.

In addition, the light scattering agent 111 can improve the phenomenon in which colors appear differently depending on the left and right positions and angles based on the position of the substrate 240.

As an example of such light scattering agent 111, Zr oxide (ZrO₂) may be used. Zr oxide may interfere with straightness of light emitted from the light source (e.g., LEDs) forming the sub-pixels (210, 220, 230) to cause light scattering that is one type of random reflection.

As mentioned above, Zr oxide (e.g., ZrO₂) used as the light scattering agent 111 is a material with a high refractive index (e.g., 2.3), and may thus have a relatively large scattering effect.

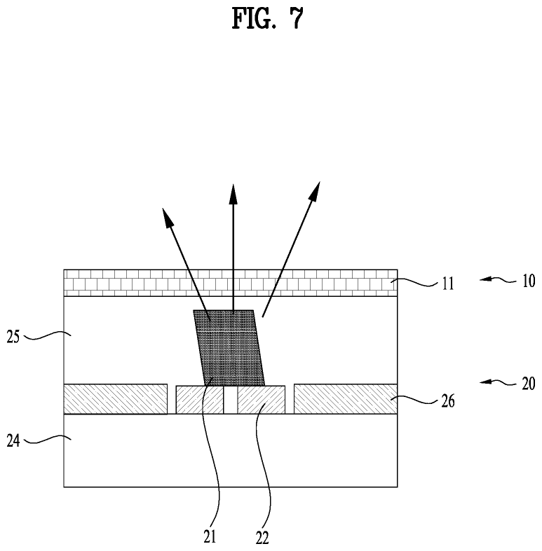

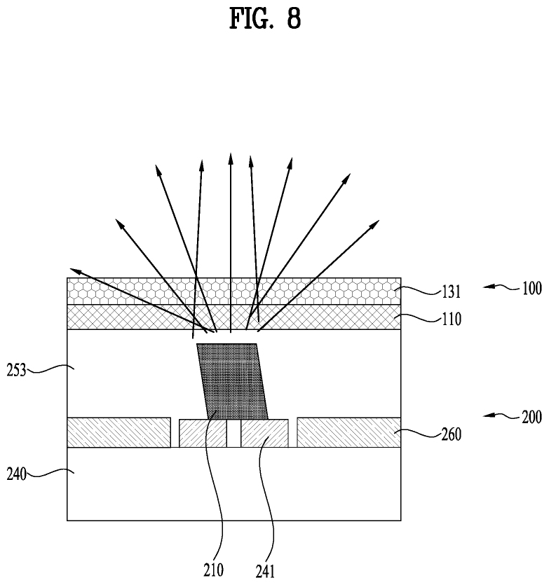

FIGS. 7 and 8 are cross-sectional schematic diagrams illustrating example states that compensate for light distribution of the display device provided with the composite optical film according to an embodiment of the present disclosure.

The composite optical film 100 according to an embodiment of the present disclosure described above may supplement a difference in light distribution due to the chip inclination of a light emitting device (e.g., LED) constituting the sub-pixels (210, 220, 230), and may also supplement a difference in directivity angle of the red, green, and blue LEDs.

Referring to FIG. 7, a general composite optical film 10 including an adhesive layer 11 that does not contain the light scattering agent may be disposed on the display panel 20.

In the display panel 20, a wiring electrode 22 may be disposed on the substrate 24 in which a sub-pixel area is defined by an insulation layer 26 (serving as a barrier), and a light emitting device 21 (e.g., a light emitting diode LED) forming a sub-pixel may be disposed on the wiring electrode 22 is provided. At this time, the encapsulation layer 25 may be located on the LED 21 and the insulation layer 26.

When such a general composite optical film 10 is located on the display panel 20, depending on the chip inclination of the LED 21, light emitted from this LED 21 may have a directivity angle that is biased to one side from the center point of the chip.

The LED 21 usually has a compound semiconductor crystal grown on a crystal substrate such as sapphire, such that the LED 21 may have a chip inclination as schematically shown in FIG. 7.

The reason why the LED 21 has the chip inclination may be due to characteristics of the crystal plane in a chip fabrication process. Generally, the substrate or compound semiconductor crystal forming the LED 21 has a hexagonal inclined crystal plane. Therefore, when LEDs 21 are grown and cut into a plurality of chips by such crystal planes, each of the LEDs 21 is not cut in a perfectly vertical direction. In other words, each of the LEDs 21 may have a vertical cross-sectional shape of a parallelogram rather than a rectangular parallelepiped shape.

In addition, the chip inclination of the LED 21 may occur due to a tilt (or inclination) caused by soldering or adhesion of the LED 21. That is, when soldering or adhering the LED to the wiring electrode 22, a tilt (or inclination) may occur due to non-uniformity of the solder or adhesive.

Accordingly, as shown in FIG. 7, light emitted from the LED 21 may be characterized in that the directivity angle is not uniform and is biased to one side with respect to the center point of the chip of the LED 21.

At this time, when using a general composite optical film 10, non-uniform light distribution due to the chip inclination may be directly exposed. As a result, the luminance deviation phenomenon in which light emitted from the display panel 20 is biased toward a specific direction may occur. Thus, color differences may occur depending on the viewing angle of the display device.

Meanwhile, referring to FIG. 8, the composite optical film 100 including the adhesive layer 110 containing the light scattering agent 111 according to an embodiment of the present disclosure is disposed on the display panel 200. As described above, the black dye layer 131 may be located on the adhesive layer 110. Additionally, the optical function layers (140, 150, 160) that provide optical functions are disposed on the black dye layer 131 as shown in FIG. 7, the scope or spirit of the present disclosure is not limited thereto, and the optical function layers (140, 150, 160) are omitted from FIG. 8

As described above, in the display panel 200, the wiring electrode 241 may be disposed on the substrate 240 where a sub-pixel area is defined by an insulation layer 260 (serving as a barrier) on the display panel 200, and a light emitting device 210 (e.g., LED) constituting the sub-pixel may be disposed on the wiring electrode 241. At this time, the encapsulation layer 250 may be disposed on the LED 210 and the insulation layer 260.

The LED 210 shown in FIG. 8 may also have a chip inclination as schematically shown in FIG. 7. The characteristics of the LED 210 having this chip inclination may be the same as described above with reference to FIG. 7.

However, when the composite optical film 100 having the characteristics described above is placed on the display panel 200, non-uniform light distribution caused by the chip inclination of the LED 210 can be uniformized.

As a result, the luminance deviation phenomenon in which light emitted from the display panel 210 is biased in a specific direction can be resolved. Thus, it is possible to implement uniform colors without causing color differences depending on the viewing angle of the display device.

In this way, the phenomenon (e.g., non-uniform reduction in luminance) in which colors appear differently to a user depending on the user's position and angle with respect to the display panel 200 can be improved.

Referring to FIG. 8, light emitted from the light emitting device 210 may be characterized in that the directivity angle of the light is non-uniform and biased to one side with respect to the chip center of the LED 21 as shown in FIG. 7, but such non-uniform light distribution may be uniformly emitted by the composite optical film 100.

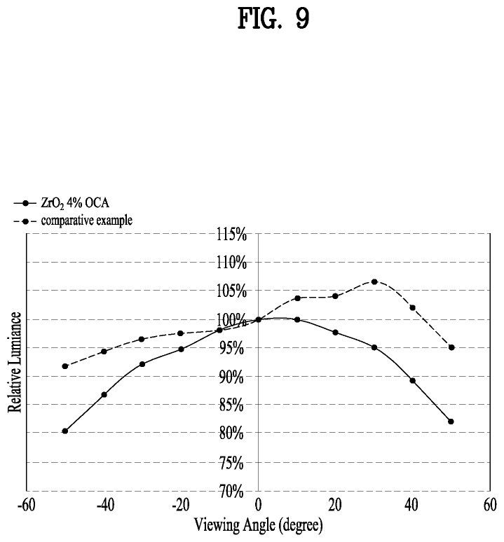

FIG. 9 is a graph showing changes in white luminance for each viewing angle of the composite optical film 100 according to an embodiment of the present disclosure.

Referring to FIG. 9, distribution of luminance of white light according to a viewing angle is shown. As a comparative example, when a general composite optical film 10 as shown in FIG. 7 is used, it can be seen that luminance distribution of the display panel is biased toward a positive (+) angle with respect to 0 degrees.

However, according to an embodiment of the present disclosure, for example, when the composite optical film 100 containing Zr oxide (ZrO₂) having a content of 4% compared to the adhesive layer 110 is applied to the display panel, it can be seen that there is a uniform luminance distribution at both of a positive angle and a negative angle with respect to 0 degrees.

In this way, the composite optical film 100 containing Zr oxide (ZrO₂) can prevent the luminance deviation phenomenon of the display panel 200.

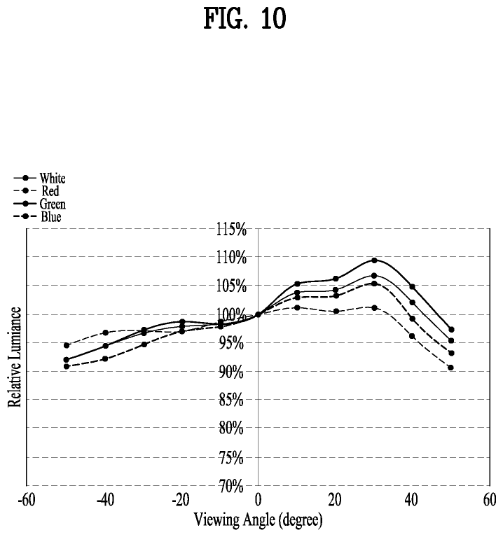

FIG. 10 is a graph showing changes in luminance for each pixel affected by the composite optical film according to comparative examples of the present disclosure.

FIG. 10 shows the luminance distribution according to the viewing angles of red, green, and blue LEDs (i.e., R, G, and B LEDs) of the display device described as a comparative example of FIG. 9.

In FIG. 10, the luminance distribution of mixed light (e.g., white light) of the LEDs for each color is roughly consistent with that of the comparative example of FIG. 9.

In this way, it can be seen that the luminance distribution depending on the viewing angles of the red RED, the green RED, and the blue RED has the luminance distribution biased toward a positive angle based on 0 degrees.

Additionally, it can be seen that the degree of such bias varies depending on each color. For example, the red LED may have a relatively uniform luminance distribution. In addition, it can be seen that the green LED and the blue LED exhibit a relatively higher non-uniformity of the light distribution. This may be due to the characteristics of a sapphire substrate and a gallium nitride semiconductor crystal used in the green and blue LEDs.

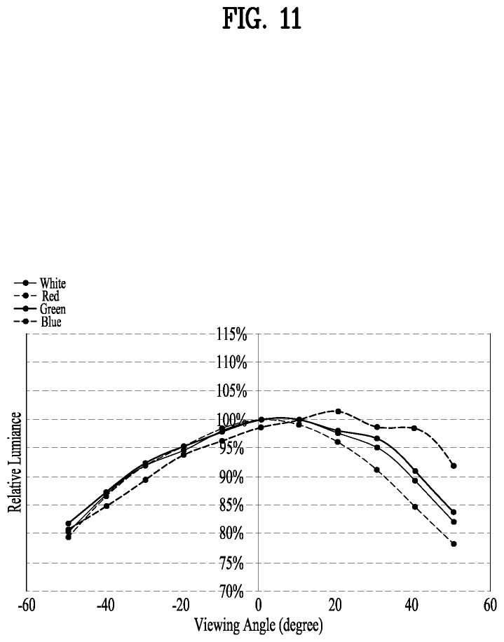

FIG. 11 is a graph showing changes in luminance for each pixel affected by the composite optical film according to an embodiment of the present disclosure.

FIG. 11 shows the luminance distribution according to the viewing angles of the red, green, and blue LEDs of the display device described in FIG. 9.

In FIG. 11, the luminance distribution of mixed light (e.g., white light) of LEDs for each color is roughly consistent with that of the example of FIG. 9 in which the composite optical film 100 containing Zr oxide (ZrO₂) is used.

In this way, when the display device according to an embodiment of the present disclosure is used, it can be seen that the luminance distribution depending on the viewing angles of the red RED, the green RED, and the blue RED has a uniform luminance distribution with respect to 0 degrees.

As described above, the light scattering agent 111 or the composite optical film 100 including this light scattering agent 111 can compensate for a difference in directivity angle between the LEDs.

Additionally, the light scattering agent 111 or the composite optical film 100 including the light scattering agent 111 can compensate for asymmetry between the viewing angles of the LEDs. That is, the light scattering agent 111 or the composite optical film 100 including this light scattering agent 111 can compensate for light distribution affected by the chip inclination (tilt) of the LEDs.

The features, structures, effects, etc. described in the embodiments above are included in at least one embodiment of the present disclosure and are not necessarily limited to only one embodiment. Furthermore, the features, structures, effects, and the like illustrated in each embodiment can be combined or modified for other embodiments by a person skilled in the art to which the embodiments belong. Therefore, subject matter related to such combinations and modifications should be construed as being included in the scope of the present disclosure.

In addition, although the present disclosure has been described focusing on the above embodiments, the embodiments are merely examples, and the scope of the present disclosure is not limited thereto, and various modifications and applications, which are not illustrated in the present embodiment, are possible without departing from the essential characteristics of the present embodiment. For example, each component specifically shown in the embodiments can be modified and implemented. Further, differences related to such modifications and applications are to be construed as being included in the scope of the present disclosure defined in the appended claims.

### INDUSTRIAL APPLICABILITY

The embodiments of the present disclosure can provide the composite optical film disposed on the display panel, and the display device including the same.

What is claimed is:

1. A display device comprising:
a display panel; and
a composite optical film disposed on the display panel,
wherein the composite optical film includes:
an adhesive layer attached to the display panel and configured to contain a light scattering agent,
wherein
the light scattering agent has a higher refractive index than the adhesive layer.

2. The display device according to claim 1, wherein:
the light scattering agent includes at least one of Zr, Si, Ti, Zn, BaS, and oxides thereof.

3. The display device according to claim 1, wherein:
the light scattering agent includes Zr oxide.

4. The display device according to claim 1, wherein:
the refractive index of the light scattering agent is about 1.3 to 2.8.

5. The display device according to claim 1, wherein:
a content of the light scattering agent is about 0.01% to 20% compared to the adhesive layer.

6. The display device according to claim 1, wherein the composite optical film includes:
a transparent protective layer disposed on the adhesive layer;
a black dye layer disposed on the transparent protective layer; and
an optical function layer disposed on the black dye layer to provide at least one optical function.

7. The display device according to claim 6, wherein the optical functional layer includes:
at least one of an anti-reflection (AR) or Anti-Glare (AG) film, a low-reflection (LR) film, and an anti-fingerprint (AF) film.

8. The display device according to claim 1, wherein the display panel includes:
red, green, and blue light emitting diodes (LEDs) configured to constitute each pixel.

9. The display device according to claim 8, wherein:
the light scattering agent compensates for a difference in directivity angle between the light emitting diodes (LEDs).

10. The display device according to claim 8, wherein:
the light scattering agent compensates for light distribution that is biased to one side due to a tilt of a crystal plane of each of the LEDs or a tilt caused by soldering or adhesion of the LED.

11. The display device according to claim 8, further comprising:
a black layer disposed at a side surface of the LED.

12. The display device according to claim 8, wherein:
the light scattering agent has a size of about 0.01 to 10 μm.

13. A composite optical film disposed on a display panel comprising:
an adhesive layer attached to the display panel and configured to contain a light scattering agent;
a transparent protective layer disposed on the adhesive layer;
a black dye layer disposed on the transparent protective layer; and
an optical function layer disposed on the black dye layer to provide at least one optical function.

14. The composite optical film according to claim 13, wherein:
the light scattering agent includes at least one of Zr, Si, Ti, Zn, BaS, and oxides thereof.

15. The composite optical film according to claim 13, wherein:
the light scattering agent includes Zr oxide.

16. The composite optical film according to claim 13, wherein:
the refractive index of the light scattering agent is about 1.3 to 2.8.

17. The composite optical film according to claim 13, wherein:
a content of the light scattering agent is about 0.01% to 20% compared to the adhesive layer.

18. The composite optical film according to claim 13, wherein:
the light scattering agent has a size of about 0.01 to 10 μm.
